(19) United States
(12) Patent Application Publication
(10) Pub. No.: US 2026/0173893 A1
(43) Pub. Date: Jun. 18, 2026

(54) SEMICONDUCTOR DEVICE

(71) Applicant: RENESAS ELECTRONICS CORPORATION, Tokyo (JP)

(72) Inventor: Yoshihiro MASUMURA, Tokyo (JP)

(21) Appl. No.: 19/398,189

(22) Filed: Nov. 24, 2025

(30) Foreign Application Priority Data
Dec. 12, 2024 (JP) 2024-217559

(51) Int. Cl. H10W 44/20; H10D 84/00

(52) U.S. Cl. CPC H10W 44/209; H10D 84/201; H10W 15/00; H10W 20/422

(57) ABSTRACT

substrate; a first insulating layer formed on the semiconductor substrate; first and second coils formed on the first insulating layer and located adjacent to each other in plan view; a first conductor pattern formed on the semiconductor substrate, extending in a second direction perpendicular to a first direction in plan view, and formed between the first coil and the second coil in the first direction; a second insulating layer formed on the first insulating layer so as to cover the first coil, the second coil, and the first conductor pattern; third and fourth coils formed on the second insulating layer and respectively overlapping the first and second coils in plan view. Here, the first direction is an arrangement direction of the first coil and the second coil. Also, the first conductor pattern is electrically connected to the semiconductor substrate.

### CROSS-REFERENCE TO RELATED APPLICATIONS

The disclosure of Japanese Patent Application No. 2024-217559 filed on Dec. 12, 2024, including the specification, drawings and abstract is incorporated herein by reference in its entirety.

### BACKGROUND

The present disclosure relates to a semiconductor device.

There are disclosed techniques listed below.
[Patent Document 1] International Publication No. 2014/097425

Patent Document 1 discloses a semiconductor device having a semiconductor substrate, a first insulating layer, a first coil, a second insulating layer, and a second coil. The first insulating layer is formed on the upper surface of the semiconductor substrate. The first coil is formed on the first insulating layer. The second insulating layer is formed on the first insulating layer so as to cover the first coil. The second coil is formed on the second insulating layer and overlaps the first coil in plain view. Patent Document 1 discloses a semiconductor device in which communication is performed between a first coil and a second coil.

### SUMMARY

In the semiconductor device disclosed in Patent Document 1, when attempting to provide multiple communication channels, there is a risk of crosstalk occurring between adjacent communication channels. Other problems and novel features will become apparent from the description herein and from the accompanying drawings.

The semiconductor device of the present disclosure includes a semiconductor substrate, a first insulating layer, a first coil, a second coil, a first conductor pattern, a second insulating layer, a third coil, and a fourth coil. The semiconductor substrate has an upper surface, and a lower surface located opposite the upper surface. The first insulating layer is formed on the upper surface. The first coil is formed on the first insulating layer. The second coil is located adjacent to the first coil in plain view. The first conductor pattern is formed on the first insulating layer, extends in a second direction perpendicular to a first direction, and is formed between the first coil and the second coil in the first direction. The first direction is an arrangement direction of the first coil and the second coil in plain view. The second insulating layer is formed on the first insulating layer so as to cover the first coil, the second coil, and the first conductor pattern. The third coil is formed on the second insulating layer and overlaps the first coil in plain view. The fourth coil is formed on the second insulating layer and overlaps the second coil in plain view. The first conductor pattern is electrically connected to the semiconductor substrate.

According to the semiconductor device of the present disclosure, crosstalk between adjacent communication channels can be suppressed.

### BRIEF DESCRIPTION OF THE DRAWINGS

FIG. 1 is a block diagram of the semiconductor device DEV1 according to the first embodiment.

FIG. 2 is an explanatory diagram showing an example of signal transmission from semiconductor chip CHP1 to semiconductor chip CHP2.

FIG. 3 is a first plan view of semiconductor chip CHP3.

FIG. 4 is a second plan view of semiconductor chip CHP3.

FIG. 5 is a third plan view of semiconductor chip CHP3.

FIG. 6 is a cross-sectional view of semiconductor chip CHP3 at VI-VI in FIG. 4.

FIG. 7 is a cross-sectional view of semiconductor chip CHP3 at VII-VII in FIG. 4.

FIG. 8 is a plan view of semiconductor chip CHP3 according to a modified example.

FIG. 9 is a manufacturing process diagram of semiconductor chip CHP3.

FIG. 10 is a cross-sectional view explaining the impurity diffusion layer formation process S2.

FIG. 11 is a cross-sectional view explaining the interlayer insulating film formation process S3.

FIG. 12 is a cross-sectional view explaining the contact plug formation process S4.

FIG. 13 is a cross-sectional view explaining the wiring layer formation process S5.

FIG. 14 is a cross-sectional view explaining the interlayer insulating film formation process S6.

FIG. 15 is a cross-sectional view explaining the via plug formation process S7.

FIG. 16 is a cross-sectional view of semiconductor chip CHP3 in semiconductor device DEV2 according to a comparative example.

FIG. 17 is a simulation result showing the relationship between signal frequency and the magnitude of crosstalk in Sample 1 and Sample 2.

FIG. 18 is a plan view of semiconductor chip CHP3 in semiconductor device DEV3 according to the second embodiment.

### DETAILED DESCRIPTION

The details of the embodiment of the present disclosure will be described with reference to the drawings. In the following drawings, the same reference numerals are assigned to the same or corresponding parts, and redundant descriptions will not be repeated.

### First Embodiment

A semiconductor device DEV1 according to the first embodiment will be described.

### Outline of Semiconductor Device DEV1

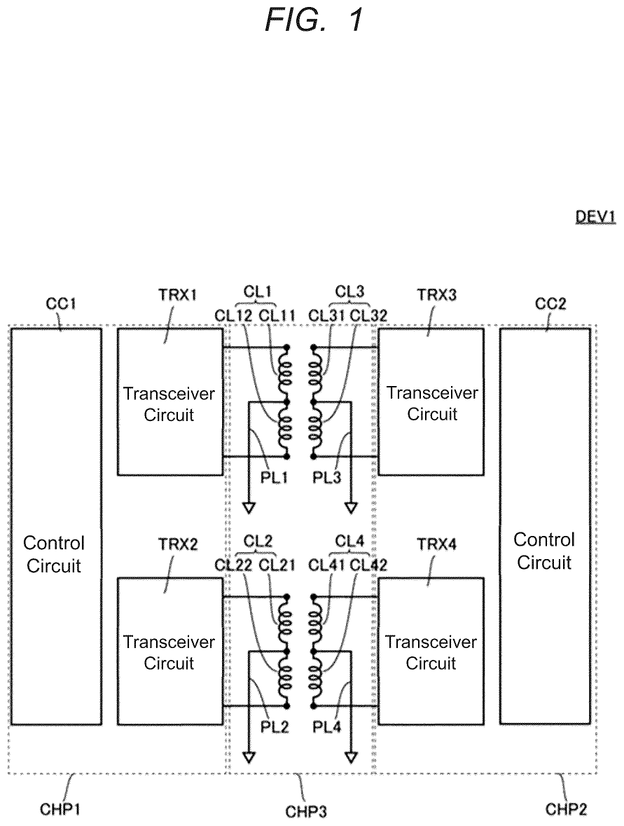

As shown in FIG. 1, the semiconductor device DEV1 includes a semiconductor chip CHP1 and a semiconductor chip CHP2. The semiconductor chip CHP1 includes a transceiver circuit TRX1, a transceiver circuit TRX2, and a control circuit CC1. The semiconductor chip CHP2 includes a transceiver circuit TRX3, a transceiver circuit TRX4, and a control circuit CC2.

The semiconductor device DEV1 further includes a semiconductor chip CHP3. The semiconductor chip CHP3 includes coils CL1, CL2, CL3, and CL4, and lead-out wirings PL1, PL2, PL3, and PL4.

The coil CL1 includes coils CL11 and CL12. One end of the coil CL11 is electrically connected to the transceiver circuit TRX1. The other end of the coil CL11 is connected to one end of the coil CL12. The other end of the coil CL12 is electrically connected to the transceiver circuit TRX1. The coil CL2 includes coils CL21 and CL22. One end of the coil CL21 is electrically connected to the transceiver circuit TRX2. The other end of the coil CL21 is connected to one end of the coil CL22. The other end of the coil CL22 is electrically connected to the transceiver circuit TRX2.

The coil CL3 includes coils CL31 and CL32. One end of the coil CL31 is electrically connected to the transceiver circuit TRX3. The other end of the coil CL31 is connected to one end of the coil CL32. The other end of the coil CL32 is electrically connected to the transceiver circuit TRX3. The coil CL4 includes coils CL41 and CL42. One end of the coil CL41 is electrically connected to the transceiver circuit TRX4. The other end of the coil CL41 is connected to one end of the coil CL42. The other end of the coil CL42 is electrically connected to the transceiver circuit TRX4.

The lead-out wiring PL1 is connected to the other end of the coil CL11 and one end of the coil CL12. The lead-out wiring PL2 is connected to the other end of the coil CL21 and one end of the coil CL22. The lead-out wiring PL3 is connected to the other end of the coil CL31 and one end of the coil CL32. The lead-out wiring PL4 is connected to the other end of the coil CL41 and one end of the coil CL42. The control circuit CC1 is electrically connected to the transceiver circuit TRX1 and the transceiver circuit TRX2. The control circuit CC2 is electrically connected to the transceiver circuit TRX3 and the transceiver circuit TRX4.

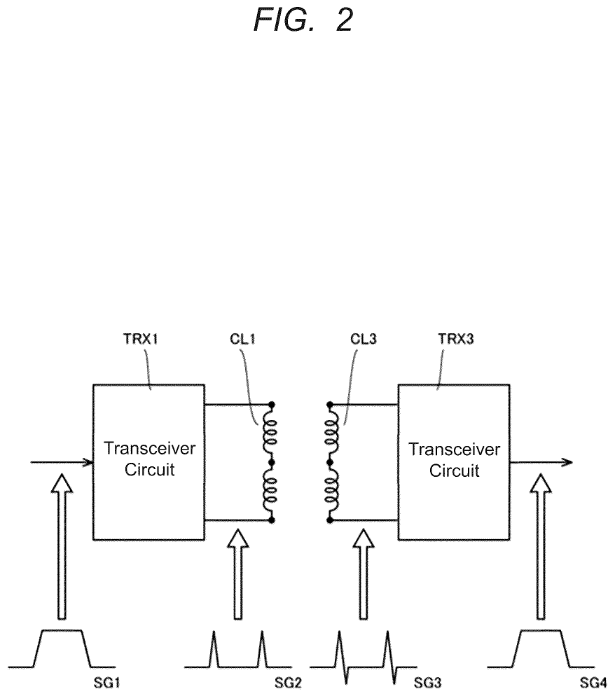

As shown in FIG. 2, the control circuit CC1 outputs a signal SG1 to the transceiver circuit TRX1. The signal SG1 is a square wave. The transceiver circuit TRX1 modulates the signal SG1 into a signal SG2 and sends the signal SG2 to the coil CL1. When the signal SG2 flows through the coil CL1, a signal SG3 corresponding to the signal SG2 flows through the coil CL3 due to induced electromotive force. The transceiver circuit TRX3 amplifies the signal SG3 and demodulates the amplified signal SG3 into a signal SG4. The transceiver circuit TRX3 outputs the signal SG4 to the control circuit CC2. By performing the reverse operation, signals are transmitted from the control circuit CC2 to the control circuit CC1. Similarly, between the control circuit CC1 and the control circuit CC2, signal transmission and reception are performed using the transceiver circuit TRX2, the transceiver circuit TRX4, the coil CL2, and the coil CL4.

### Configuration of Semiconductor Chip CHP3

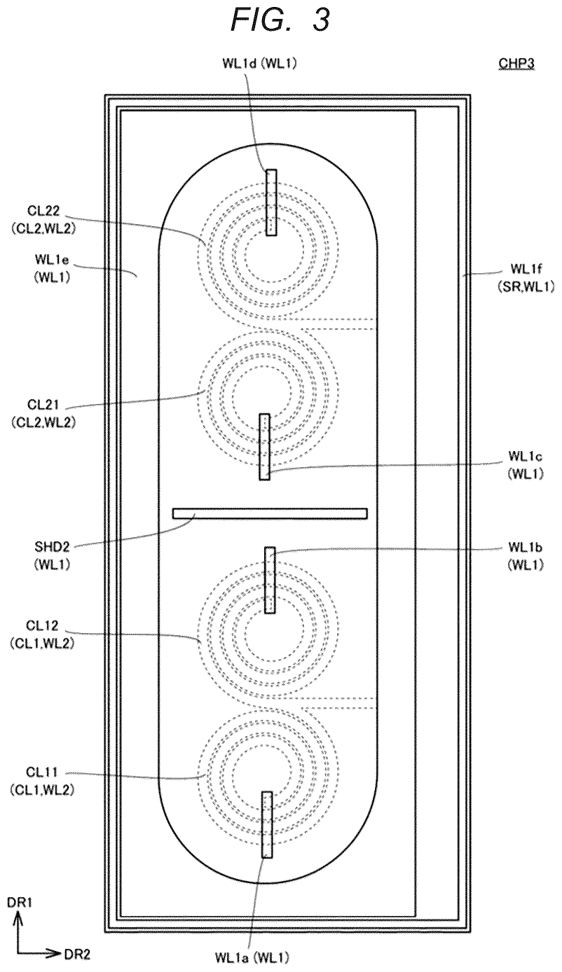

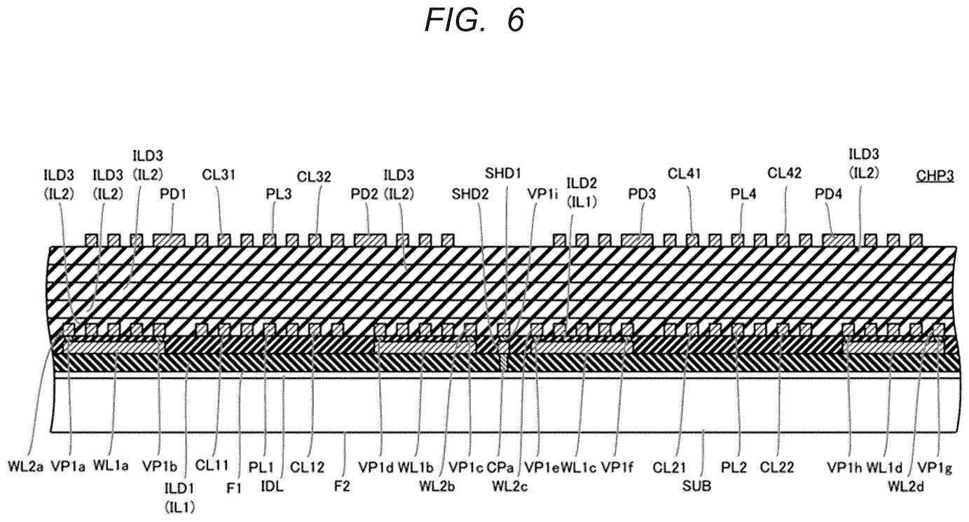

As shown in FIGS. 3, 4, 5, 6, and 7, the semiconductor chip CHP3 includes a semiconductor substrate SUB. The semiconductor substrate SUB is formed of, for example, single-crystal silicon. The semiconductor substrate SUB has an upper surface F1 and a lower surface F2 located opposite the upper surface F1. The conductivity type of the semiconductor substrate SUB is, for example, p-type. The semiconductor substrate SUB includes an impurity diffusion layer IDL. The conductivity type of the impurity diffusion layer IDL is, for example, p-type. The impurity concentration in the impurity diffusion layer IDL is higher than the impurity concentration in the semiconductor substrate SUB at locations other than the impurity diffusion layer IDL. The impurity diffusion layer IDL is formed in the semiconductor substrate SUB closer to the upper surface F1 than the lower surface F2. More specifically, the impurity diffusion layer IDL is formed on the upper surface F1 in the semiconductor substrate SUB.

The semiconductor chip CHP3 further includes an interlayer insulating film ILD1. The interlayer insulating film ILD1 is formed of, for example, silicon oxide. The interlayer insulating film ILD1 is formed on the upper surface F1.

The semiconductor chip CHP3 further includes a wiring layer WL1. The wiring layer WL1 is formed on the interlayer insulating film ILD1. The wiring layer WL1 is formed of, for example, aluminum or an aluminum alloy. The wiring layer WL1 is formed on the interlayer insulating film ILD1. The wiring layer WL1 includes wiring WL1a, WL1b, WL1c, and WL1d. As shown in FIG. 3, each of the wirings WL1a, WL1b, WL1c, and WL1d is arranged with intervals in the first direction DR1, and all extend in the first direction DR1.

The semiconductor chip CHP3 further includes an interlayer insulating film ILD2. The interlayer insulating film ILD2 is formed of, for example, silicon oxide. The interlayer insulating film ILD2 is formed on the interlayer insulating film ILD1 so as to cover the wiring layer WL1. The interlayer insulating film ILD1 and the interlayer insulating film ILD2 together form the insulating layer IL1.

The semiconductor chip CHP3 further includes a wiring layer WL2. The wiring layer WL2 is formed on the interlayer insulating film ILD2 (insulating layer IL1). The wiring layer WL2 is formed of, for example, aluminum or an aluminum alloy. The wiring layer WL2 includes coils CL1 (coils CL11, CL12) and coils CL2 (coils CL21, CL22).

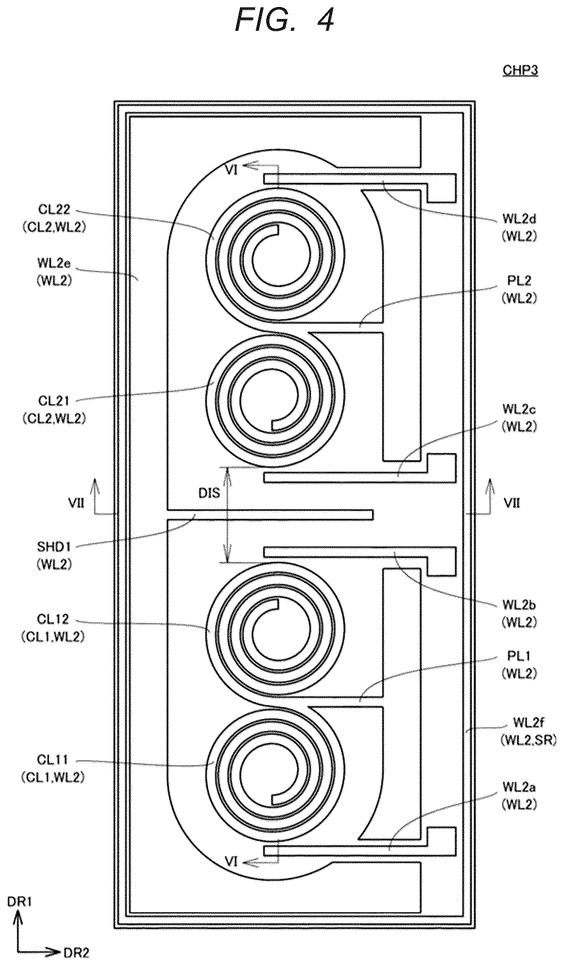

As shown in FIGS. 3 and 4, the coils CL1 and CL2 are arranged with intervals in the first direction DR1. More specifically, the coils CL1 and CL2 are arranged with intervals in the first direction DR1 such that the coil CL12 is positioned next to the coil CL21.

The coil CL11 is wound in a spiral shape in plain view. More specifically, the coil CL11 is wound counterclockwise in plain view from one end located at the innermost periphery to the other end located at the outermost periphery. The coil CL12 is wound in a spiral shape in plain view. More specifically, the coil CL12 is wound clockwise in plain view from one end located at the outermost periphery to the other end located at the innermost periphery. The other end of the coil CL11 is connected to one end of the coil CL12.

The coil CL21 is wound in a spiral shape in plain view. More specifically, the coil CL21 is wound counterclockwise in plain view from one end located at the innermost periphery to the other end located at the outermost periphery. The coil CL22 is wound in a spiral shape in plain view. More specifically, the coil CL22 is wound clockwise in plain view from one end located at the outermost periphery to the other end located at the innermost periphery. The other end of the coil CL21 is connected to one end of the coil CL22.

The wiring layer WL2 further includes wiring WL2a, WL2b, WL2c, and WL2d. Each of the wirings WL2a, WL2b, WL2c, and WL2d extends in the second direction DR2, which is perpendicular to the first direction DR1 in plain view.

One end of the wiring WL2a is positioned next to the coil CL11. One end of the wiring WL2a overlaps with one end of the wiring WL1a in plain view. One end of the coil CL11 overlaps with the other end of the wiring WL1a in plain view. One end of the wiring WL2b is positioned next to the coil CL12. One end of the wiring WL2b overlaps with one end of the wiring WL1b in plain view. One end of the coil CL12 overlaps with the other end of the wiring WL1b in plain view.

One end of the wiring WL2c is positioned next to the coil CL21. One end of the wiring WL2c overlaps with one end of the wiring WL1c in plain view. One end of the coil CL21 overlaps with the other end of the wiring WL1c in plain view. One end of the wiring WL2d is positioned next to the coil CL22. One end of the wiring WL2d overlaps with one end of the wiring WL1d in plain view. One end of the coil CL22 overlaps with the other end of the wiring WL1d in plain view.

Additionally, the wiring layer WL2 further includes lead-out wirings PL1 and PL2. Each of the lead-out wirings PL1 and PL2 extend in the second direction DR2. One end of the lead-out wiring PL1 is connected to the other end of the coil CL11 and one end of the coil CL12. One end of the lead-out wiring PL2 is connected to the other end of coil CL21 and one end of coil CL22.

The semiconductor chip CHP3 further includes via plug VP1a, via plug VP1b, via plug VP1c, and via plug VP1d. The semiconductor chip CHP3 further includes via plug VP1e, via plug VP1f, via plug VP1g, and via plug VP1h. Via plugs VP1a to VP1h are formed, for example, of tungsten. The via plugs VP1a to VP1h are formed in the interlayer insulating film ILD2.

The via plug VP1a connects one end of the wiring WL2a with one end of the wiring WL1a, and the via plug VP1b connects one end of the coil CL11 with the other end of the wiring WL1a. The via plug VP1c connects one end of the wiring WL2b with one end of the wiring WL1b, and the via plug VP1d connects one end of the coil CL12 with the other end of the wiring WL1b. The via plug VP1e connects one end of the wiring WL2c with one end of the wiring WL1c, and the via plug VP1f connects one end of the coil CL21 with the other end of the wiring WL1c. The via plug VP1g connects one end of the wiring WL2d with one end of the wiring WL1d, and the via plug VP1h connects one end of the coil CL22 with the other end of the wiring WL1d.

The semiconductor chip CHP3 further includes a plurality of interlayer insulating films ILD3 and a plurality of wiring layers WL3. The interlayer insulating film ILD3 is formed of, for example, silicon oxide. The plurality of interlayer insulating films ILD3 is laminated on the interlayer insulating film ILD2. The lowermost interlayer insulating film ILD3 covers the wiring layer WL2. The wiring layer WL3 is formed of, for example, aluminum or an aluminum alloy. The wiring layer WL3 is formed on one interlayer insulating film ILD3 and is covered by another interlayer insulating film ILD3 formed on the same. The plurality of interlayer insulating films ILD3 deems the insulation layer IL2.

The semiconductor chip CHP3 further includes a wiring layer WL4. The wiring layer WL4 is formed on the uppermost interlayer insulating film ILD3 (insulating layer ILD2). The wiring layer WL4 is formed of, for example, aluminum or an aluminum alloy. The wiring layer WL4 includes a coil CL3 (coil CL31, coil CL32) and a coil CL4 (coil CL41, coil CL42).

The coils CL3 and CL4 are arranged with a space between them in the first direction DR1. More specifically, the coils CL3 and CL4 are arranged with a space between them in the first direction DR1 such that the coil CL32 is positioned next to the coil CL41. The coil CL3 overlaps with the coil CL1 in plan view, and the coil CL4 overlaps with the coil CL2 in plan view.

The coil CL31 is wound in a spiral shape in plan view. More specifically, the coil CL31 is wound counterclockwise in plan view from one end located at the innermost periphery to the other end located at the outermost periphery. The coil CL32 is wound in a spiral shape in plan view. More specifically, the coil CL32 is wound clockwise in plan view from one end located at the outermost periphery to the other end located at the innermost periphery. The other end of the coil CL31 is connected to one end of the coil CL32.

The coil CL41 is wound in a spiral shape in plan view. More specifically, the coil CL41 is wound counterclockwise in plan view from one end located at the innermost periphery to the other end located at the outermost periphery. The coil CL42 is wound in a spiral shape in plan view. More specifically, the coil CL42 is wound clockwise in plan view from one end located at the outermost periphery to the other end located at the innermost periphery. The other end of the coil CL41 is connected to one end of the coil CL42.

Furthermore, the wiring layer WL4 includes lead-out wirings PL3 and PL4. Each of the lead-out wirings, PL3 and PL4 extends in the second direction DR2. One end of the lead-out wiring PL3 is connected to the other end of the coil CL31 and one end of the coil CL32. One end of the lead-out wiring PL4 is connected to the other end of the coil CL41 and one end of the coil CL42.

The wiring layer WL4 further includes a guard ring GR. The guard ring GR surrounds the coils CL3 and CL4 in plan view. The wiring layer WL4 further includes wiring WL4a, WL4b, WL4c, and WL4d. Each of the wirings WL4a, WL4b, WL4c, and WL4d are arranged with a space between them in the first direction DR1, and all extend in the first direction. The wirings WL4a, WL4b, WL4c, and WL4d are formed outside the guard ring GR in plan view.

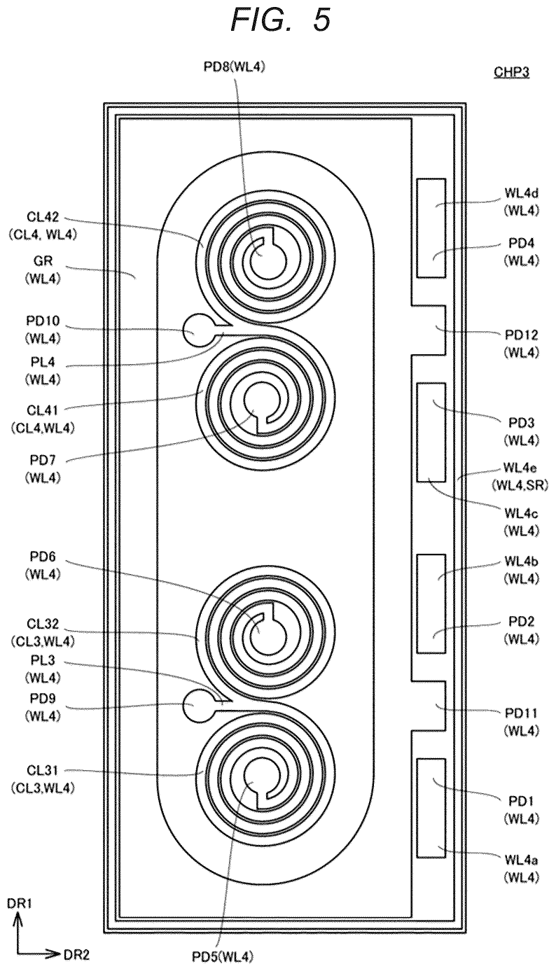

The wiring layer WL4 further includes pads PD1, PD2, PD3, PD4, PD5, PD6, PD7, and PD8. As shown in FIG. 5, the pad PD1 is connected to one end of the wiring WL4a, and the pad PD2 is connected to one end of the wiring WL4b. The pad PD3 is connected to one end of the wiring WL4c, and the pad PD4 is connected to one end of the wiring WL4d. The pad PD5 is connected to one end of the coil CL31, and the pad PD6 is connected to the other end of the coil CL32. The pad PD7 is connected to one end of the coil CL41, and the pad PD8 is connected to the other end of the coil CL42.

Although not shown, the other end of the wiring WL4a is electrically connected to the other end of the wiring WL2a, and the other end of the wiring WL4b is electrically connected to the other end of the wiring WL2b. Also, the other end of the wiring WL4c is electrically connected to the other end of the wiring WL2c, and the other end of the wiring WL4d is electrically connected to the other end of the wiring WL2d.

The wiring layer WL4 further includes pads PD9, PD10, PD11, and PD12. The pad PD9 is connected to the other end of the lead-out wiring PL3, and the pad PD10 is connected to the other end of the lead-out wiring PL4. The pads PD11 and PD12 are connected to the guard ring GR. The pads PD1, PD2, PD3, PD4, PD11, and PD12 are arranged with a space between them in the first direction DR1. The pad PD11 is positioned between the pads PD1 and PD2 in the first direction DR1. The pad PD12 is positioned between the pads PD3 and PD4 in the first direction DR1.

The semiconductor chip CHP3 is electrically connected to the semiconductor chip CHP1 (transceiver circuit TRX1) at the pads PD1 and PD2, and to the semiconductor chip CHP1 (transceiver circuit TRX2) at the pads PD3 and PD4. The semiconductor chip CHP3 is electrically connected to the semiconductor chip CHP2 (transceiver circuit TRX3) at the pads PD5 and PD6, and to the semiconductor chip CHP2 (transceiver circuit TRX4) at the pads PD7 and PD8.

The wiring layer WL2 further includes a conductor pattern SHD1. The conductor pattern SHD1 extends in the second direction DR2 between the coil CL1 (coil CL12) and the coil CL2 (coil CL21). The wiring layer WL1 further includes a conductor pattern SHD2. The conductor pattern SHD2 extends in the second direction DR2 and overlaps with the conductor pattern SHD1 in plan view.

The semiconductor chip CHP3 further includes a plurality of via plugs VP1i. The via plugs VP1i are formed of, for example, tungsten. The via plugs VP1i are formed in the interlayer insulating film ILD2. The plurality of via plugs VP1i is arranged with a space between them in the second direction DR2. The plurality of via plugs VP1i overlaps with the conductor patterns SHD1 and SHD2 in plan view.

The semiconductor chip CHP3 further includes a plurality of contact plugs CPa. The contact plugs CPa are formed of, for example, tungsten. The contact plugs CPa are formed in the interlayer insulating film ILD1. The plurality of contact plugs CPa is arranged with a space between them in the second direction DR2. The plurality of contact plugs CPa overlaps with the conductor pattern SHD2 in plan view. The conductor pattern SHD1 is electrically connected to the semiconductor substrate SUB (impurity diffusion layer IDL) through the plurality of via plugs VP1i, the conductor pattern SHD2, and the plurality of contact plugs CPa.

The guard ring GR is electrically connected to the conductor pattern SHD1. More specifically, the wiring layer WL2 further includes wiring WL2e. As shown in FIG. 4, the wiring WL2e surrounds the coils CL1 and CL2 (coils CL3 and CL4) in plan view. Each of the plurality of wiring layers WL3 includes a wiring WL3a. Although not shown, the wiring WL3a surrounds the coils CL1 and CL2 (coils CL3 and CL4) in plan view.

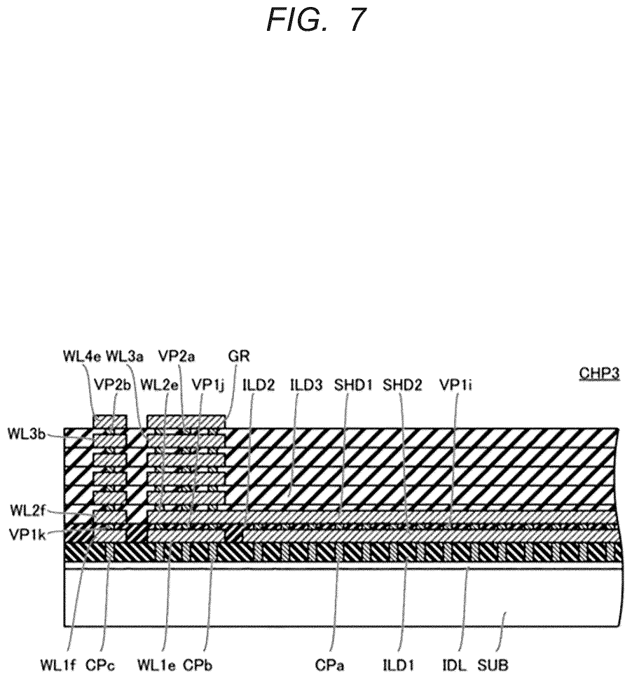

The semiconductor chip CHP3 further includes a plurality of via plugs VP2a. The via plugs VP2a are formed of, for example, tungsten. As shown in FIG. 7, the plurality of via plugs VP2a is each formed in the plurality of interlayer insulating films ILD3. The plurality of via plugs VP2a is respectively connected between the wiring WL2e and the wiring WL3a provided in the lowermost wiring layer WL3 among the plurality of wiring layers WL3, between the wiring WL3a provided in two adjacent wiring layers WL3 among the plurality of wiring layers WL3, and between the guard ring GR and the wiring WL3a provided in the uppermost wiring layer WL3 among the plurality of wiring layers WL3. The conductor pattern SHD1 is connected to the wiring WL2e. In this manner, the conductor pattern SHD1 is electrically connected to the guard ring GR.

The guard ring GR is also electrically connected to the semiconductor substrate SUB (impurity diffusion layer IDL). More specifically, the wiring layer WL1 further includes the wiring WL1e. The wiring WL1e surrounds the coils CL1 and CL2 (coils CL3 and CL4) in plan view. The semiconductor chip CHP3 further includes a plurality of via plugs VP1j and a plurality of contact plugs CPb. The via plugs VP1j and contact plugs CPb are formed, for example, from tungsten. The via plugs VP1j are formed in the interlayer insulating film ILD2, and the contact plugs CPb are formed in the interlayer insulating film ILD1. The wiring WL2e is connected to the wiring WL1e by the plurality of via plugs VP1j, and the wiring WL1e is connected to the semiconductor substrate SUB (impurity diffusion layer IDL) by the plurality of contact plugs CPb. In this manner, the guard ring GR is also electrically connected to the semiconductor substrate SUB (impurity diffusion layer IDL).

Since the other end of the lead-out wiring PL1 and the end of the lead-out wiring PL2 are connected to the wiring WL2e, the guard ring GR is also electrically connected to the lead-out wiring PL1 and lead-out wiring PL2. A ground potential is applied to the pads PD11 and PD12. Therefore, ground potential is also applied to the conductor pattern SHD1, impurity diffusion layer IDL, lead-out wiring PL1, and lead-out wiring PL2. A ground potential will be applied to the pads PD9 and PD10. Therefore, ground potential will also be applied to the lead-out wiring PL3 and lead-out wiring PL4.

The shortest distance between the coil CL1 and the coil CL2 is referred to as the distance DIS. The distance DIS is, for example, less than 100 μm. The distance DIS may be, for example, 90 μm or less, or even 80 μm or less.

The semiconductor chip CHP3 may further include a seal ring SR. The seal ring SR is formed on the outer peripheral edge of the upper surface F1. More specifically, the wiring layer WL1 includes the wiring WL1f, the wiring layer WL2 includes the wiring WL2f, each of the plurality of wiring layers WL3 includes the wiring WL3b, and the wiring layer WL4 includes the wiring WL4e. The semiconductor chip CHP3 further includes a plurality of contact plugs CPc, a plurality of via plugs VP1k, and a plurality of via plugs VP2b.

The contact plug CPc is formed, for example, of tungsten. The contact plug CPc is formed in the interlayer insulating film ILD1. The plurality of contact plugs CPc connect the wiring WL1f and the semiconductor substrate SUB (impurity diffusion layer IDL). The via plug VP1k is formed, for example, of tungsten. The via plug VP1k is formed in the interlayer insulating film ILD2. The plurality of via plugs VP1k connects the wiring WL2f and the wiring WL1f. The via plug VP2b is formed, for example, of tungsten. The via plug VP2b is formed in the interlayer insulating film ILD3. The plurality of via plugs VP2b connects between the wiring WL2f and the wiring WL3b of the lowest wiring layer WL3, between two adjacent wiring layers WL3 among the plurality of wiring layers WL3, and between the wiring WL3b of the topmost wiring layer WL3 and the wiring WL4e. In this way, the seal ring SR is composed of the plurality of contact plugs CPc, the wiring WL1f, the plurality of via plugs VP1k, the wiring WL2f, the plurality of via plugs VP2b, the wiring WL3b, and the wiring WL4e.

### Modified Example of Semiconductor Chip CHP3

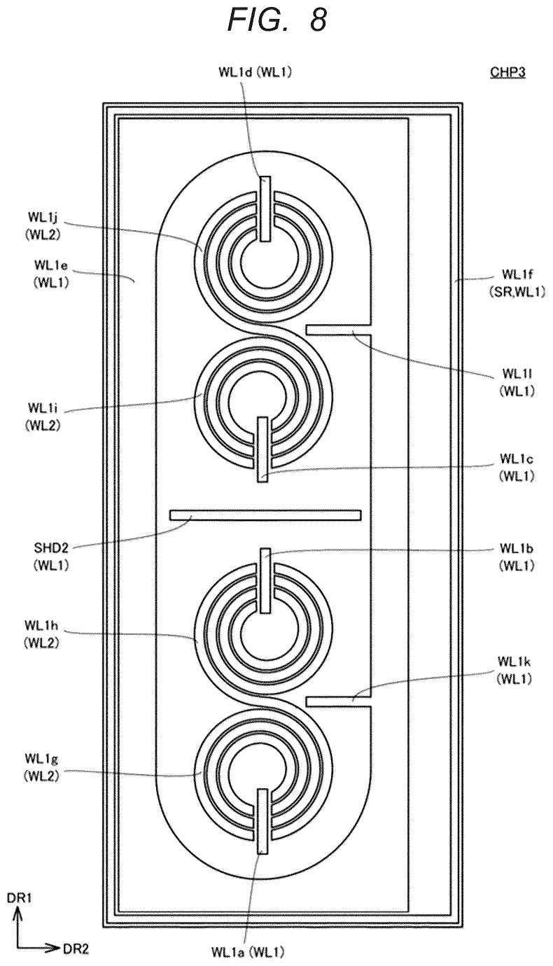

As shown in FIG. 8, the wiring layer WL1 may further include wiring WL1g, wiring WL1h, wiring WL1i, wiring WL1j, wiring WL1k, and wiring WL1l. Although not shown, the semiconductor chip CHP3 may further include a plurality of via plugs VP1l, a plurality of via plugs VP1m, a plurality of via plugs VP1n, a plurality of via plugs VP1o, a plurality of via plugs VP1p, and a plurality of via plugs VP1q.

The wiring WL1g overlaps with the coil CL11 in plain view, and the wiring WL1h overlaps with the coil CL12 in plain view. The wiring WL1i overlaps with the coil CL21 in plain view, and the wiring WL1j overlaps with the coil CL22 in plain view. The via plugs VP1l, VP1m, VP1n, and VP1o are formed, for example, of tungsten. The via plugs VP1l, VP1m, VP1n, and VP1o are formed in the interlayer insulating film ILD2. The plurality of via plugs VP1l connects the coil CL11 and the wiring WL1g, and the plurality of via plugs VP1m connects the coil CL12 and the wiring WL1h. The plurality of via plugs VP1n connects the coil CL21 and the wiring WL1i, and the plurality of via plugs VP1o connects the coil CL22 and the wiring WL1j.

The wiring WL1k overlaps with the lead-out wiring PL1 in plain view and is connected to the wiring WL1e. The wiring WL1l overlaps with the lead-out wiring PL2 in plain view and is connected to the wiring WL1e. The via plugs VP1p and VP1q are formed, for example, of tungsten. The via plugs VP1p and VP1q are formed in the interlayer insulating film ILD2. The plurality of via plugs VP1p connects the lead-out wiring PL1 and the wiring WL1k, and the plurality of via plugs VP1q connects the lead-out wiring PL2 and the wiring WL1l. In this way, the electrical resistance values of the coil CL1, coil CL2, lead-out wiring PL1, and lead-out wiring PL2 may be reduced.

### Method of Manufacturing Semiconductor Chip CHP3

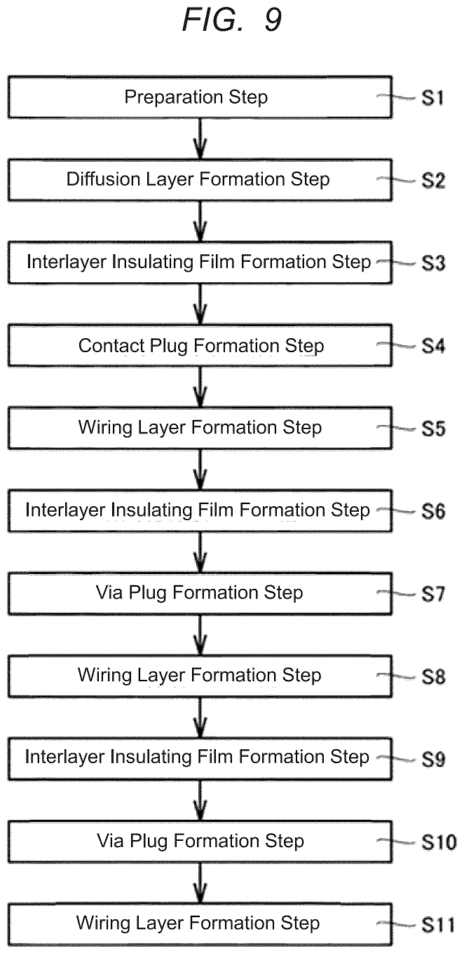

As shown in FIG. 9, the method of manufacturing the semiconductor chip CHP3 includes a preparation step S1 and an impurity diffusion layer formation step S2. Additionally, the manufacturing method of the semiconductor chip CHP3 further includes an interlayer insulating film formation step S3, a contact plug formation step S4, a wiring layer formation step S5, an interlayer insulating film formation step S6, and a via plug formation step S7.

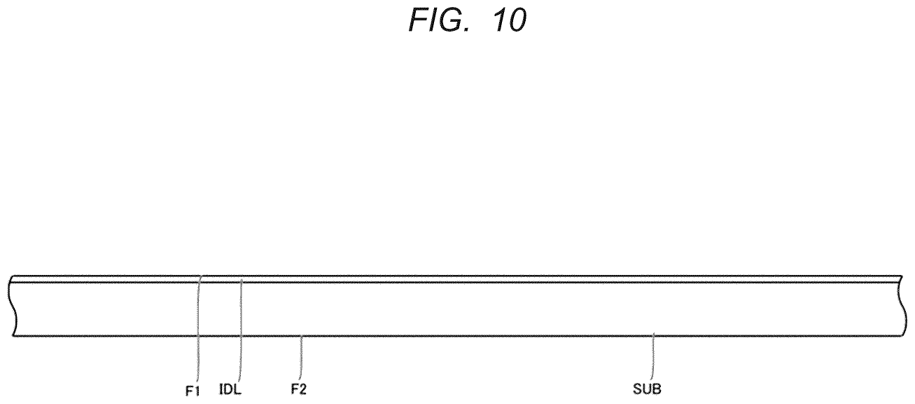

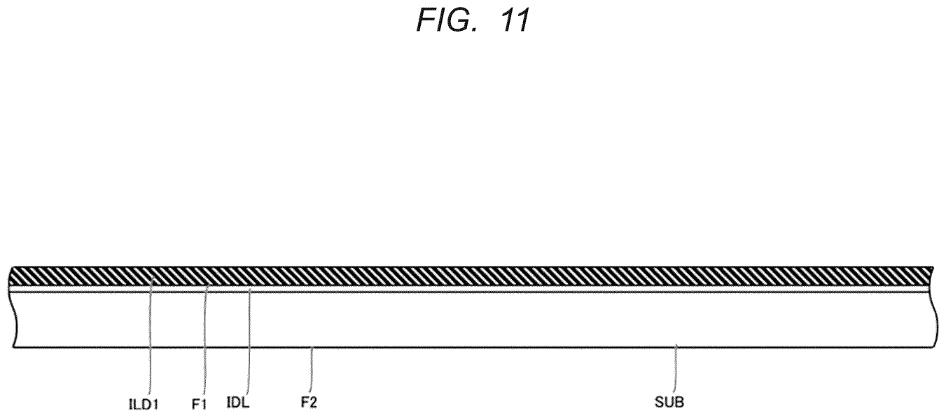

In the preparation step S1, the semiconductor substrate SUB is prepared. As shown in FIG. 10, in the impurity diffusion layer formation step S2, for example, by performing ion implantation, an impurity diffusion layer IDL is formed on the upper surface F1. As shown in FIG. 11, in the interlayer insulating film formation step S3, for example, by the CVD (Chemical Vapor Deposition) method, the interlayer insulating film ILD1 is formed on the upper surface F1.

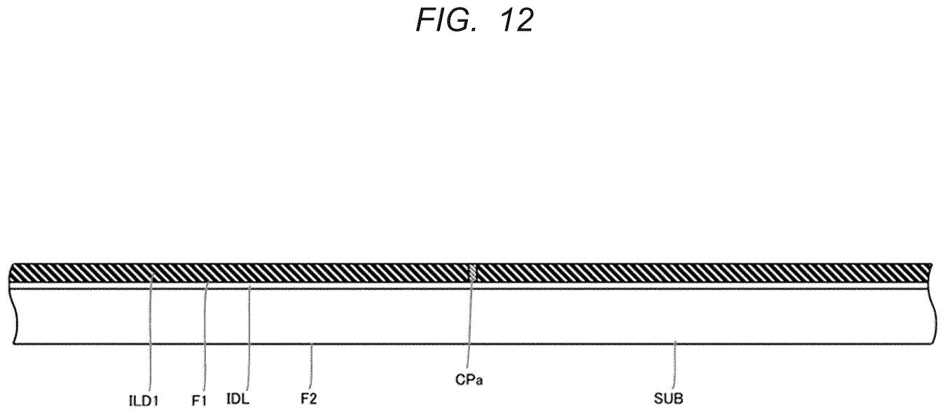

As shown in FIG. 12, in the contact plug formation step S4, contact plugs CPa, CPb, and CPc are formed. In the contact plug formation step S4, firstly, a resist pattern is formed on the interlayer insulating film ILD1. The resist pattern is formed by patterning a photoresist applied on the interlayer insulating film ILD1 using photolithography. Secondly, by performing dry etching on the interlayer insulating film ILD1 through the openings of the resist pattern, through-holes are formed in the interlayer insulating film ILD1. Thirdly, for example, by the CVD method, the constituent material of the contact plug CPa, etc., is deposited in the above through-holes and on the interlayer insulating film ILD1. Fourthly, for example, by the CMP (Chemical Mechanical Polishing) method, the constituent material of the contact plug CPa, etc., formed outside the above through-holes is removed.

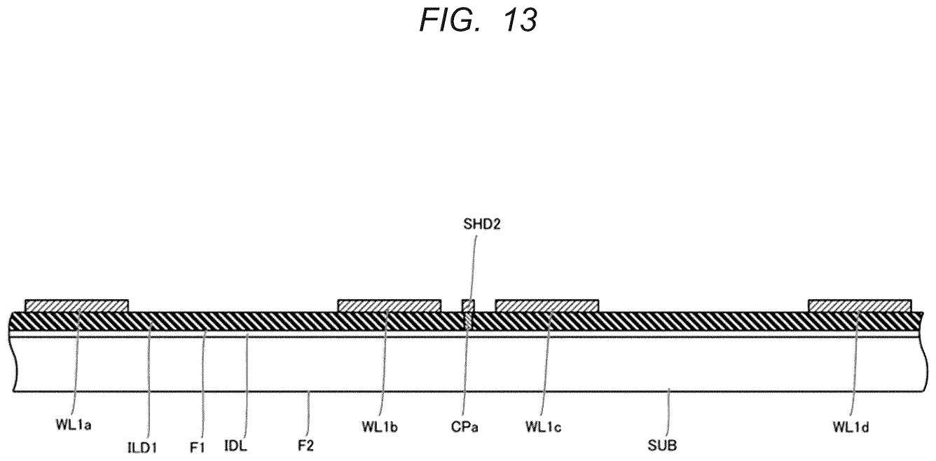

As shown in FIG. 13, in the wiring layer formation step S5, the wiring layer WL1 is formed on the interlayer insulating film ILD1. In the wiring layer formation step S5, firstly, for example, by sputtering, the constituent material of the wiring layer WL1 is formed on the interlayer insulating film ILD1. Secondly, a resist pattern is formed on the constituent material of the wiring layer WL1. The resist pattern is formed by patterning a photoresist applied on the wiring layer WL1 using photolithography. Thirdly, by performing dry etching on the constituent material of the wiring layer WL1 through the openings of the resist pattern, the constituent material of the wiring layer WL1 is patterned.

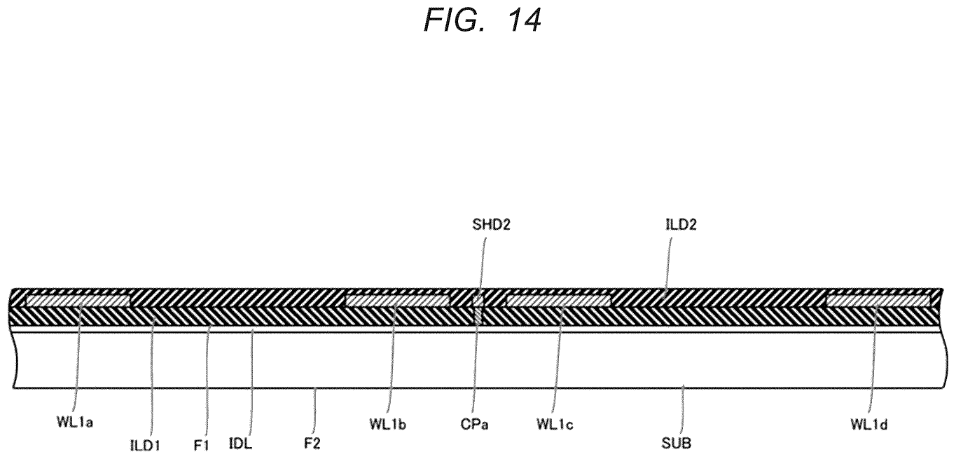

As shown in FIG. 14, in the interlayer insulating film formation step S6, the interlayer insulating film ILD2 is formed on the interlayer insulating film ILD1 so as to cover the wiring layer WL1. In the interlayer insulation film formation step S6, firstly, for example, by the CVD method, the constituent material of the interlayer insulating film ILD2 is formed on the interlayer insulating film ILD1. Secondly, the upper surface of the constituent material of the interlayer insulating film ILD2 is planarized, for example, by the CMP method.

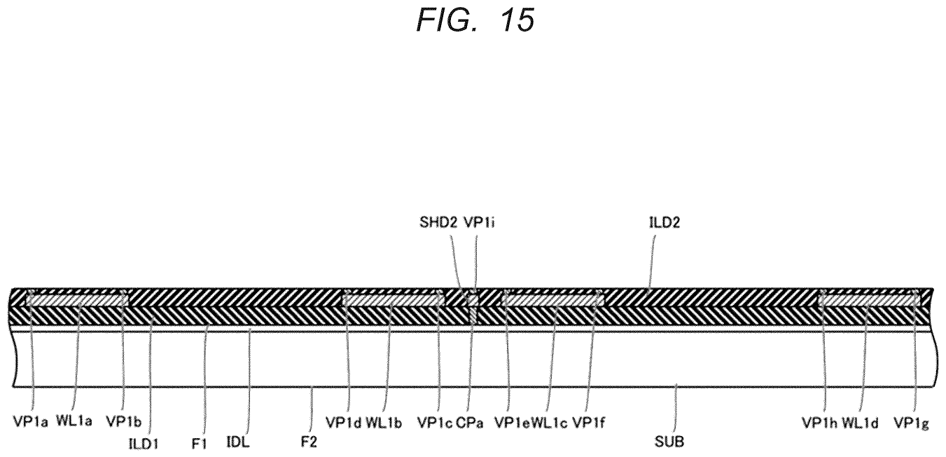

As shown in FIG. 15, in the via plug formation step S7, via plugs VP1a to VP1k are formed in the interlayer insulating film ILD1. In the via plug formation step S7, firstly, a resist pattern is formed on the interlayer insulating film ILD2. The resist pattern is formed by patterning a photoresist applied on the interlayer insulating film ILD2 using photolithography. Secondly, by performing dry etching on the interlayer insulating film ILD2 through the openings of the resist pattern, through-holes are formed in the interlayer insulating film ILD2. Thirdly, for example, by the CVD method, the constituent material of the via plug VP1a, etc., is deposited in the above through-holes and on the interlayer insulating film ILD2. Fourthly, for example, by the CMP method, the constituent material of the via plug VP1a, etc., formed outside the above through-holes is removed.

As shown in FIG. 9, the manufacturing method of the semiconductor chip CHP3 further includes a wiring layer formation step S8, an interlayer insulating film formation step S9, a via plug formation step S10, and a wiring layer formation step S11.

In the wiring layer formation step S8, similarly to the wiring layer formation step S5, the wiring layer WL2 is formed. In the interlayer insulating film formation step S9, similarly to the interlayer insulating film formation step S6, the interlayer insulating film ILD3 is formed. In the via plug formation step S10, similarly to the via plug formation step S7, via plugs VP2a and VP2b are formed. By repeating the wiring layer formation step S8, the interlayer insulating film formation step S9, and the via plug formation step S10, the plurality of wiring layers WL3 and the plurality of interlayer insulating films ILD3 are formed up to the topmost layer, and via plugs VP2a and VP2b are formed in each of the plurality of interlayer insulating films ILD3. In the wiring layer formation step S11, similarly to the wiring layer formation step S5, the wiring layer WL4 is formed. As a result, the structure of the semiconductor chip CHP3 shown in FIGS. 1 to 7 is formed.

### Effect of Semiconductor Device DEV1

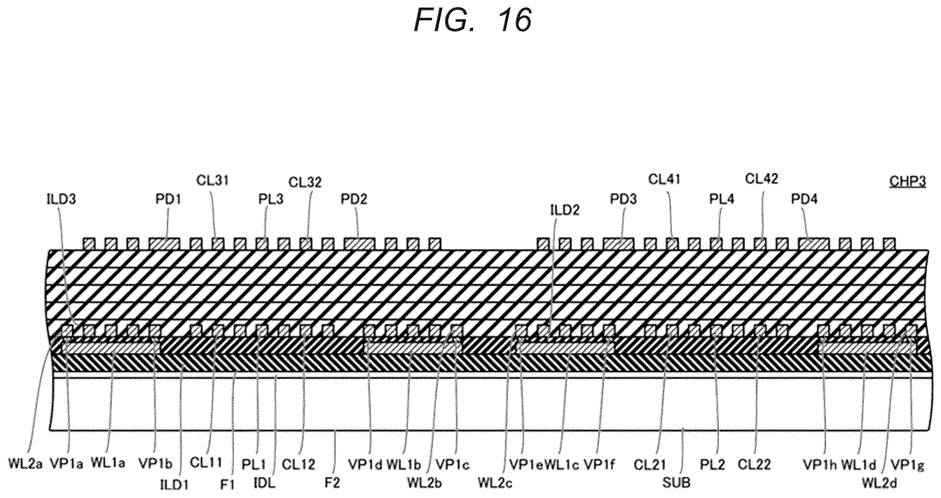

As shown in FIG. 16, the semiconductor chip CHP3 of the semiconductor device DEV2 according to the comparative example does not have a conductor pattern SHD1, a conductor pattern SHD2, a plurality of via plugs VP1i, and a plurality of contact plugs CPa. As a result, when signals are transmitted from coil CL1 to coil CL3, coil CL1 and coil CL2 may become coupled, potentially causing crosstalk between communication channels.

On the other hand, in the semiconductor chip CHP3 of the semiconductor device DEV1, a conductor pattern SHD1 is formed between the coil CL1 and the coil CL2, and the conductor pattern SHD1 is electrically connected to the semiconductor substrate SUB (particularly, the impurity diffusion layer IDL) through the plurality of via plugs VP1i, conductor pattern SHD2, and the plurality of contact plugs CPa. As a result, ground potential is applied to the conductor pattern SHD1. Therefore, in the semiconductor chip CHP3 of the semiconductor device DEV1, the above-mentioned coupling is suppressed by the conductor pattern SHD1. In this way, according to the semiconductor chip CHP3 of the semiconductor device DEV1, crosstalk between communication channels can be suppressed.

From another perspective, in the semiconductor chip CHP3 of the semiconductor device DEV1, crosstalk between communication channels can be suppressed without increasing the distance DIS, allowing the semiconductor chip CHP3 to be shrunk by reducing the distance DIS. If the conductor pattern SHD1 is also electrically connected to the guard ring GR, the potential applied to the conductor pattern SHD1 becomes stable, further suppressing crosstalk between communication channels.

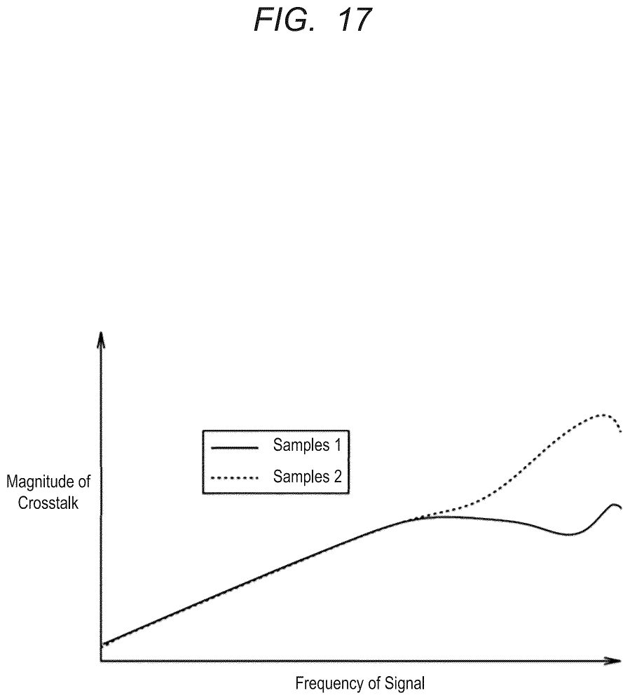

In FIG. 17, the horizontal axis represents the frequency of the signal transmitted from coil CL1 to coil CL3, and the vertical axis indicates the magnitude of crosstalk. The horizontal axis in FIG. 17 is displayed logarithmically. The simulation shown in FIG. 17 includes samples 1 and 2. Sample 1 corresponds to the semiconductor chip CHP3 of the semiconductor device DEV1, and sample 2 corresponds to the semiconductor chip CHP3 of the semiconductor device DEV2. As shown in FIG. 17, it can be seen that in sample 1, compared to sample 2, crosstalk significantly decreases in the high-frequency region of the transmitted signal.

### Second Embodiment

The semiconductor device DEV3 according to the second embodiment will be described. Here, the differences from the semiconductor device DEV1 will be mainly explained, and repetitive descriptions will not be repeated.

### Configuration of Semiconductor Device DEV3

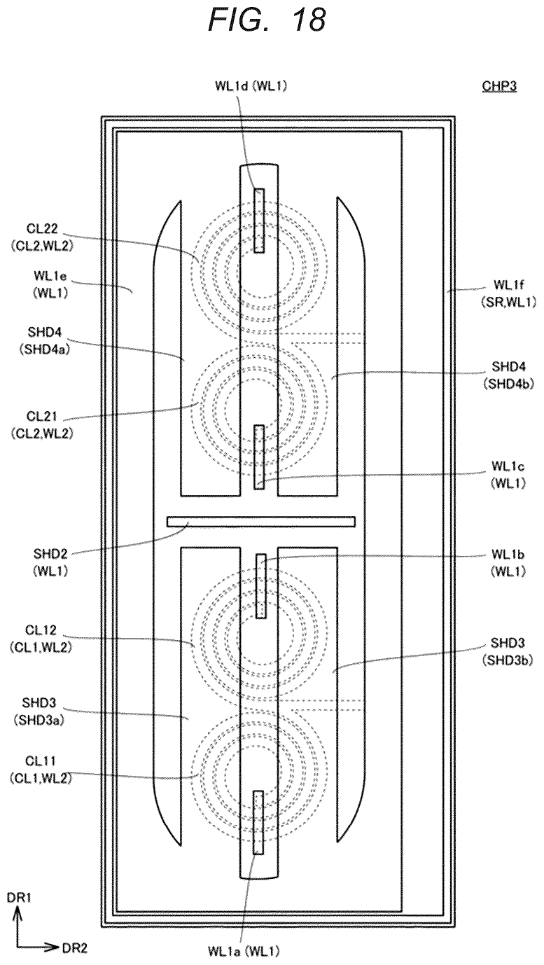

The semiconductor device DEV3 includes semiconductor chips CHP1, CHP2, and CHP3. In the semiconductor device DEV3, the configuration of the semiconductor chip CHP3 differs from that of the semiconductor device DEV3. More specifically, as shown in FIG. 18, the semiconductor chip CHP3 of the semiconductor device DEV3 has a wiring layer WL1 that includes conductor patterns SHD3 and SHD4.

The conductor pattern SHD3 overlaps with the coil CL1 (coil CL11, coil CL12) in plain view. The conductor pattern SHD4 overlaps with the coil CL2 (coil CL21, coil CL22) in plain view. The conductor patterns SHD3 and SHD4 are connected to the wiring WL1e. Therefore, the conductor patterns SHD3 and SHD4 are electrically connected to the guard ring GR, and a ground potential is applied.

The conductor pattern SHD3 includes a first portion SHD3a and a second portion SHD3b. The second portion SHD3b is formed at a distance from the first portion SHD3a. In the example shown in FIG. 18, the first portion SHD3a and the second portion SHD3b are arranged at intervals in the second direction DR2, but the arrangement of the first portion SHD3a and the second portion SHD3b is not limited to this. Additionally, the conductor pattern SHD3 may be divided into three or more parts formed at intervals from each other.

The conductor pattern SHD4 includes a third portion SHD4a and a fourth portion SHD4b. The fourth portion SHD4b is formed at a distance from the third portion SHD4a. In the example shown in FIG. 18, the third portion SHD4a and the fourth portion SHD4b are arranged at intervals in the second direction DR2, but the arrangement of the third portion SHD4a and the fourth portion SHD4b is not limited to this. Additionally, the conductor pattern SHD4 may be divided into three or more parts formed at intervals from each other.

### Effect of Semiconductor Device DEV3

In the semiconductor chip CHP3 of the semiconductor device DEV1, direct coupling between the coil CL1 and the coil CL2 is suppressed by the conductor pattern SHD1. However, since the impurity diffusion layer IDL is formed on the semiconductor substrate SUB, the electrical resistance value of the semiconductor substrate SUB is reduced, and thus, the coil CL1 and the coil CL2 may be indirectly coupled to each other through the impurity diffusion layer IDL.

On the other hand, in the semiconductor chip CHP3 of the semiconductor device DEV3, the conductor pattern SHD3 is formed between the coil CL1 and the impurity diffusion layer IDL, and the conductor pattern SHD4 is formed between the coil CL2 and the impurity diffusion layer IDL. Additionally, ground potential is applied to the conductor patterns SHD3 and SHD4. Therefore, in the semiconductor chip CHP3 of the semiconductor device DEV3, coupling between the coil CL1 and the impurity diffusion layer IDL, coupling between the coil CL2 and the impurity diffusion layer IDL, and consequently indirect coupling between the coil CL1 and the coil CL2 via the impurity diffusion layer IDL are suppressed. In this way, according to the semiconductor device DEV3, crosstalk between communication channels is further suppressed. Moreover, if the conductor patterns SHD3 and SHD4 are divided into a plurality of parts formed separately, the generation of eddy currents in the conductor patterns SHD3 and SHD4 is suppressed.

Although the invention made by the inventor has been specifically described based on the embodiment, the present invention is not limited to the embodiment described above, and it is needless to say that various modifications can be made without departing from the gist thereof.

What is claimed is:

1. A semiconductor device comprising:
a semiconductor substrate having an upper surface and a lower surface located opposite the upper surface;
a first insulating layer formed on the upper surface;
a first coil formed on the first insulating layer;
a second coil formed on the first insulating layer and located adjacent to the first coil in plan view;
a first conductor pattern formed on the first insulating layer, extending in a second direction perpendicular to a first direction, and formed between the first coil and the second coil in the first direction, the first direction being an arrangement direction of the first coil and the second coil in plan view;
a second insulating layer formed on the first insulating layer so as to cover the first coil, the second coil, and the first conductor pattern;
a third coil formed on the second insulating layer and overlapping the first coil in plan view; and
a fourth coil formed on the second insulating layer and overlapping the second coil in plan view,
wherein the first conductor pattern is electrically connected to the semiconductor substrate.

2. The semiconductor device according to claim 1,
wherein the semiconductor substrate has an impurity diffusion layer formed in the semiconductor substrate at a position closer to the upper surface than the lower surface, and
wherein the first conductor pattern is electrically connected to the impurity diffusion layer.

3. The semiconductor device according to claim 2, further comprising:
a second conductor pattern;
a plurality of via plugs; and
a plurality of contact plugs,
wherein the first insulating layer includes: a first interlayer insulating film formed on the upper surface of the semiconductor substrate; and a second interlayer insulating film formed on the first interlayer insulating film,
wherein the second conductor pattern is formed on the first interlayer insulating film, covered by the second interlayer insulating film, and extends in the second direction so as to overlap the first conductor pattern in plan view,
wherein the plurality of via plugs is formed in the second interlayer insulating film so as to overlap the first conductor pattern in plan view,
wherein the plurality of contact plugs is formed in the first interlayer insulating film so as to overlap the second conductor pattern in plan view, and
wherein the first conductor pattern is electrically connected to the semiconductor substrate through the plurality of via plugs, the second conductor pattern, and the plurality of contact plugs.

4. The semiconductor device according to claim 3, wherein the first conductor pattern is electrically connected to the impurity diffusion layer through the plurality of via plugs, the second conductor pattern, and the plurality of contact plugs.

5. The semiconductor device according to claim 4, further comprising:
a guard ring surrounding the third coil and the fourth coil in plan view,
wherein the guard ring is electrically connected to each of the first conductor pattern and the impurity diffusion layer.

6. The semiconductor device according to claim 1, further comprising:
a third conductor pattern; and
a fourth conductor pattern,
wherein the first insulating layer includes: a first interlayer insulating film formed on the upper surface; and a second interlayer insulating film formed on the first interlayer insulating film,
wherein the third conductor pattern and the fourth conductor pattern are formed on the first interlayer insulating film and covered by the second interlayer insulating film,
wherein the third conductor pattern overlaps the first coil in plan view, and
wherein the fourth conductor pattern overlaps the second coil in plan view.

7. The semiconductor device according to claim 6,
wherein the third conductor pattern includes a first portion, and a second portion formed spaced apart from the first portion, and
wherein the fourth conductor pattern includes a third portion, and a fourth portion formed spaced apart from the third portion.

8. The semiconductor device according to claim 7, further comprising:
a guard ring surrounding the third coil and the fourth coil in plan view,
wherein the guard ring is electrically connected to each of the third conductor pattern and the fourth conductor pattern.

9. The semiconductor device according to claim 1, wherein a minimum distance between the first coil and the second coil in the first direction is less than 100 μm.
